(19) United States
(12) Patent Application Publication
(10) Pub. No.: US 2024/0030109 A1
(43) Pub. Date: Jan. 25, 2024

(54) SEMICONDUCTOR DEVICE

(71) Applicant: ROHM CO., LTD., Kyoto-shi (JP)

(72) Inventors: Yoshizo OSUMI, Kyoto-shi (JP); Taro NISHIOKA, Kyoto-shi (JP); Hiroaki MATSUBARA, Kyoto-shi (JP)

(21) Appl. No.: 18/474,654

(22) Filed: Sep. 26, 2023

Related U.S. Application Data
(63) Continuation of application No. PCT/JP2022/009400, filed on Mar. 4, 2022.

(30) Foreign Application Priority Data
Mar. 29, 2021 (JP) 2021-054572

(51) Int. Cl. H01L 23/495; H01L 23/00

(52) U.S. Cl. CPC H01L 23/49562; H01L 23/49503; H01L 24/48; H01L 24/45; H01L 2924/13091; H01L 2224/48247; H01L 2224/45144

(57) ABSTRACT

A semiconductor device includes: a plurality of conductive members including a first die pad and a second die pad that are spaced apart from each other; a first semiconductor element mounted on the first die pad; a second semiconductor element mounted on the second die pad; and an insulator that is electrically connected to the first semiconductor element and the second semiconductor element, and that insulates the first semiconductor element and the second semiconductor element from each other. The plurality of conductive members include a third die pad spaced apart from the first die pad and the second die pad. The insulator is mounted on the third die pad.

### TECHNICAL FIELD

The present disclosure relates to a semiconductor device provided with a plurality of semiconductor elements and an insulating element that insulates the semiconductor elements from each other.

### BACKGROUND ART

Inverters used in electric vehicles (including hybrid vehicles) and home appliances include semiconductor devices. For example, an inverter includes a semiconductor device and a switching element such as an insulated gate bipolar transistor (IGBT) or a metal oxide semiconductor field effect transistor (MOSFET). The semiconductor device includes a control element (controller) and a drive element (gate driver). In the inverter, a control signal outputted from an external source is inputted to the control element of the semiconductor device. The control element converts the control signal into a pulse width modulation (PWM) control signal and transmits the PWM control signal to the drive element. The drive element causes, for example, six switching elements to drive at a desired timing based on the PWM control signal. As a result, three-phase AC power for motor driving is generated from DC power. JP-A-2016-207714 discloses an example of a semiconductor device used for a motor driving device.

According to the semiconductor device disclosed in JP-A-2016-207714, the source voltage supplied to a control element is different from the source voltage supplied to a drive element, which causes a difference in applied source voltage between two conductive paths, i.e., a conductive path to the control element and a conductive path to the drive element. In view of this, an insulating element is provided between the conductive path to the control element and the conductive path to the drive element so as to improve the dielectric strength of the semiconductor device. The insulating element is mounted on a die pad on which either the control element or the drive element is mounted. Accordingly, when there is a significant difference in the source voltage applied to each of the two conductive paths, the insulating element will have a high risk of dielectric breakdown. It is therefore necessary to take some measures to avoid the risk.

### BRIEF DESCRIPTION OF THE DRAWINGS

FIG. 1 is a plan view illustrating a semiconductor device according to a first embodiment of the present disclosure.

FIG. 2 is a plan view corresponding to FIG. 1, as seen through a sealing resin.

FIG. 3 is a front view illustrating the semiconductor device in FIG. 1.

FIG. 4 is a rear view illustrating the semiconductor device in FIG. 1.

FIG. 5 is a left-side view illustrating the semiconductor device in FIG. 1.

FIG. 6 is a cross-sectional view taken along line VI-VI in FIG. 2.

FIG. 7 is a cross-sectional view taken along line VII-VII in FIG. 2.

FIG. 8 is a schematic view illustrating an insulating element and a third die pad, which are also illustrated in FIG. 6.

FIG. 9 is a plan view illustrating a semiconductor device according to a second embodiment of the present disclosure, as seen through a sealing resin.

FIG. 10 is a front view illustrating the semiconductor device in FIG. 9.

FIG. 11 is a rear view illustrating the semiconductor device in FIG. 9.

FIG. 12 is a plan view illustrating a semiconductor device according to a third embodiment of the present disclosure, as seen through a sealing resin.

FIG. 13 is a partially enlarged view of FIG. 12.

FIG. 14 is a cross-sectional view taken along line XIV-XIV in FIG. 12.

FIG. 15 is a schematic view illustrating an insulating element and a third die pad, which are also illustrated in FIG. 14.

### DETAILED DESCRIPTION OF EMBODIMENTS

Embodiments of the present disclosure will be described with reference to the accompanying drawings.

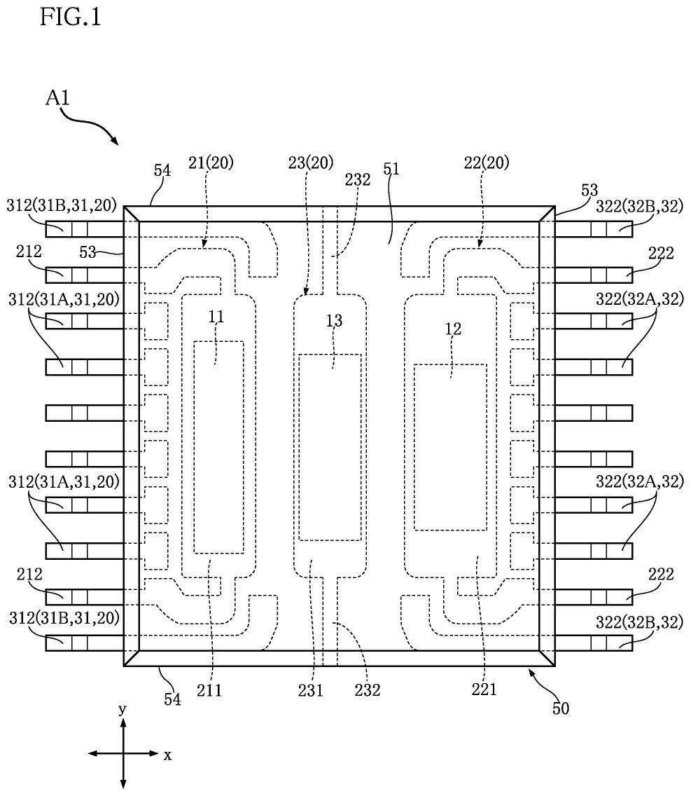

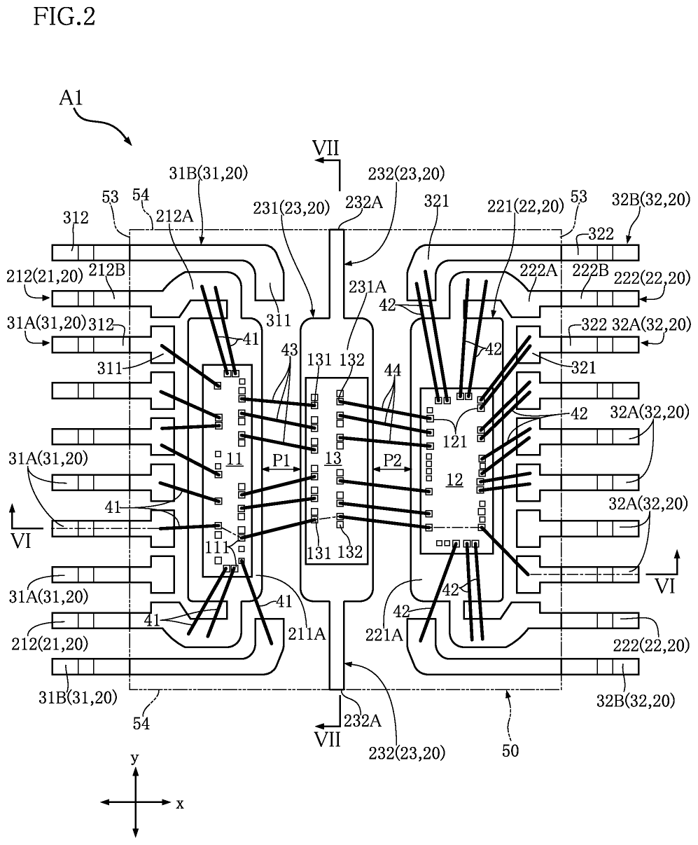

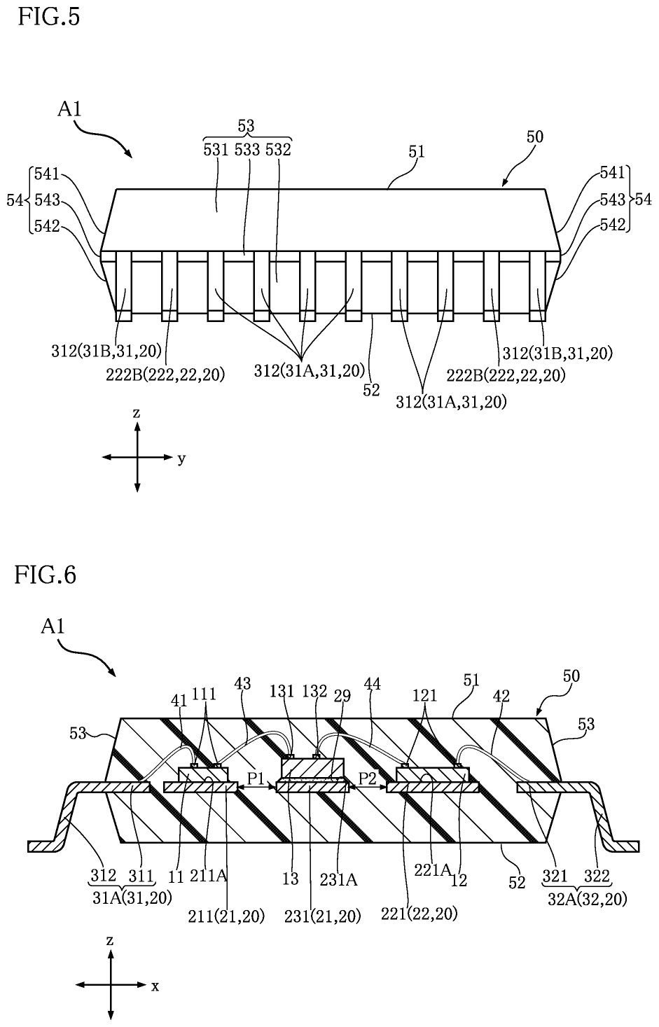

The following describes a semiconductor device A1 according to a first embodiment of the present disclosure, with reference to FIGS. 1 to 8. The semiconductor device A1 includes a first semiconductor element 11, a second semiconductor element 12, an insulating element 13, a plurality of conductive members 20, a bonding layer 29, a plurality of first wires 41, a plurality of second wires 42, a plurality of third wires 43, a plurality of fourth wires 44, and a sealing resin 50. The conductive members 20 include a first die pad 21, a second die pad 22, a third die pad 23, a plurality of first terminals 31, and a plurality of second terminals 32. The semiconductor device A1 is surface-mounted on the wiring board of an inverter for an electric vehicle or a hybrid vehicle, for example. The semiconductor device A1 is in a small outline package (SOP). Note that the package type of the semiconductor device A1 is not limited to an SOP. In FIG. 2, the sealing resin 50 is shown in phantom for convenience of understanding, and is indicated by an imaginary line (two-dot chain line).

In the description of the semiconductor device A1, the thickness direction of each of the first semiconductor element 11, the second semiconductor element 12, and the insulating element 13 is referred to as “thickness direction z”. A direction perpendicular to the thickness direction z is referred to as “first direction x”. The direction perpendicular to both of the thickness direction z and the first direction x is referred to as “second direction y”.

The first semiconductor element 11, the second semiconductor element 12, and the insulating element 13 form the functional core of the semiconductor device A1. In the semiconductor device A1, each of the first semiconductor element 11, the second semiconductor element 12, and the insulating element 13 is an individual element. In the first direction x, the second semiconductor element 12 is located opposite from the first semiconductor element 11 with respect to the insulating element 13. As viewed in the thickness direction z, each of the first semiconductor element 11, the second semiconductor element 12, and the insulating element 13 has a rectangular shape with its longer sides extending in the second direction y.

The first semiconductor element 11 is the controller (control element) of a gate driver for driving a switching element such as an IGBT or a MOSFET. The first semiconductor element 11 has a circuit that converts a control signal inputted from, for example, an ECU into a PWM control signal, a transmission circuit that transmits the PWM control signal to the second semiconductor element 12, and a reception circuit that receives an electric signal from the second semiconductor element 12.

The second semiconductor element 12 is the gate driver (drive element) for driving the switching element. The second semiconductor element 12 has a reception circuit that receives a PWM control signal, a circuit that drives the switching element based on the PWM control signal, and a transmission circuit that transmits an electric signal to the first semiconductor element 11. The electric signal may be an output signal from a temperature sensor located near a motor.

The insulating element 13 transmits a PWM control signal or other electric signals in an electrically insulated state. In the semiconductor device A1, the insulating element 13 is of an inductive type. An example of the inductive insulating element 13 is an insulating transformer. The insulating transformer transmits an electric signal in an electrically insulated state by inductively coupling two inductors (coils). The insulating element 13 has a silicon substrate. Inductors made of copper (Cu) are mounted on the substrate. The inductors include a transmission inductor and a reception inductor, which are stacked in the thickness direction z. A dielectric layer made of, for example, silicon dioxide (SiO₂) is provided between the transmission inductor and the reception inductor. The dielectric layer electrically insulates the transmission inductor from the reception inductor. Alternatively, the insulating element 13 may be of a capacitive type. An example of the capacitive insulating element 13 is a capacitor.

In the semiconductor device A1, the voltage applied to the first semiconductor element 11 is different from the voltage applied to the second semiconductor element 12. As a result, a potential difference is created between the first semiconductor element 11 and the second semiconductor element 12. Furthermore, in the semiconductor device A1, the source voltage supplied to the second semiconductor element 12 is higher than the source voltage supplied to the first semiconductor element 11.

Accordingly, in the semiconductor device A1, a first circuit including the first semiconductor element 11 as a component and a second circuit including the second semiconductor element 12 as a component are insulated from each other by the insulating element 13. The insulating element 13 is electrically connected to the first circuit and the second circuit. The first circuit further includes the first die pad 21, the first terminals 31, the first wires 41, and the third wires 43, in addition to the first semiconductor element 11. The second circuit further includes the second die pad 22, the second terminals 32, the second wires 42, and the fourth wires 44, in addition to the second semiconductor element 12. The first circuit has a different potential from the second circuit. In the semiconductor device A1, the second circuit has a higher potential than the first circuit. As such, the insulating element 13 relays a mutual signal between the first circuit and the second circuit. In the case of an inverter for an electric vehicle or a hybrid vehicle, the voltage applied to the ground of the first semiconductor element 11 is approximately 0 V, whereas the voltage applied to the ground of the second semiconductor element 12 becomes 600 V or higher transiently.

As shown in FIGS. 2 and 6, the first semiconductor element 11 has a plurality of first electrodes 111. The first electrodes 111 are provided on an upper surface of the first semiconductor element 11 (i.e., a surface facing in the same direction as a first mounting surface 211A of a first pad portion 211 of the first die pad 21 described below). The composition of the first electrodes 111 includes aluminum, for example. In other words, each of the first electrodes 111 contains aluminum. The first electrodes 111 are electrically connected to the circuit configured in the first semiconductor element 11.

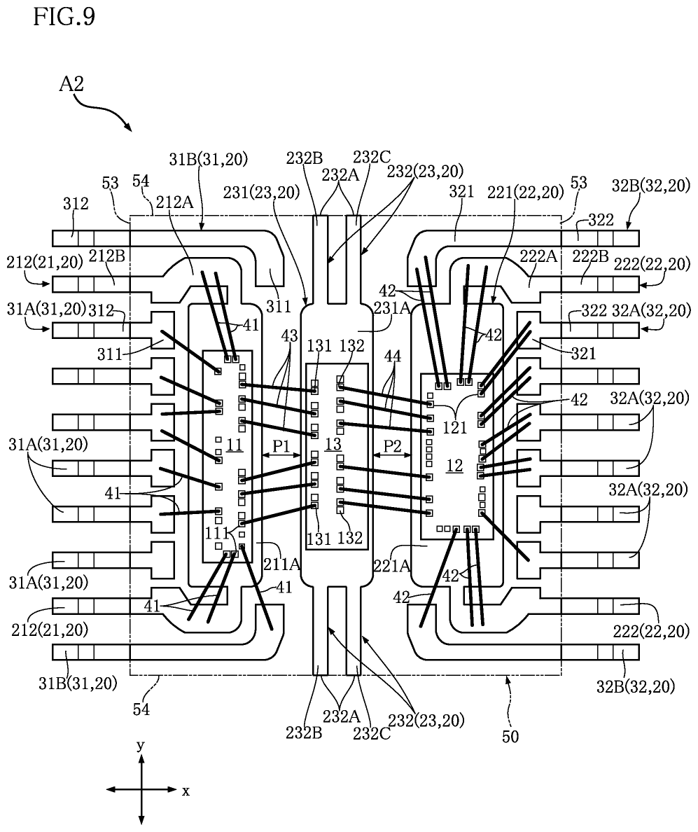

As shown in FIGS. 2 and 6, the insulating element 13 is located between the first semiconductor element 11 and the second semiconductor element 12 in the first direction x. As shown in FIGS. 8 and 9, the insulating element 13 has a plurality of first relay electrodes 131 and a plurality of second relay electrodes 132. The first relay electrodes 131 and the second relay electrodes 132 are provided on an upper surface of the insulating element 13 (i.e., a surface facing in the same direction as a third mounting surface 231A of a third pad portion 231 of the third die pad 23 described below). The first relay electrodes 131 are aligned in the second direction y, and are located closer to the first semiconductor element 11 than to the second semiconductor element 12 in the first direction x. The second relay electrodes 132 are aligned in the second direction y, and are located closer to the second semiconductor element 12 than to the first semiconductor element 11 in the first direction x.

As shown in FIG. 8, the insulating element 13 further has a first transceiver 133, a second transceiver 134, and a relay portion 135. Each of the first transceiver 133, the second transceiver 134, and the relay portion 135 is an inductor. The first transceiver 133 and the second transceiver 134 are spaced apart from each other in the first direction x. The first transceiver 133 is electrically connected to the first relay electrodes 131. Furthermore, the first transceiver 133 is electrically connected to the first semiconductor element 11 via the third wires 43. The second transceiver 134 is electrically connected to the second relay electrodes 132. Furthermore, the second transceiver 134 is electrically connected to the second semiconductor element 12 via the fourth wires 44.

As shown in FIG. 8, the relay portion 135 is located away from the first transceiver 133 and the second transceiver 134 in the thickness direction z. A dielectric layer (not illustrated) made of silicon dioxide, for example, is provided between the relay portion 135 and each of the first transceiver 133 and the second transceiver 134. The relay portion 135 transmits and receives signals between the first transceiver 133 and the second transceiver 134. In the thickness direction z, the relay portion 135 is located closer to the third pad portion 231 (detailed below) of the third die pad 23 than are the first transceiver 133 and the second transceiver 134. The potential of the relay portion 135 takes a value between the potential value of the first transceiver 133 and the potential value of the second transceiver 134.

As shown in FIGS. 2 and 6, the second semiconductor element 12 has a plurality of second electrodes 121. The second electrodes 121 are provided on an upper surface of the second semiconductor element 12 (i.e., a surface facing in the same direction as a second mounting surface 221A of a second pad portion 221 of the second die pad 22 described below). The composition of the second electrodes 121 includes aluminum, for example. The second electrodes 121 are electrically connected to the circuit configured in the second semiconductor element 12.

The conductive members 20 form a conductive path between a wiring board on which the semiconductor device A1 is mounted and each of the first semiconductor element 11, the second semiconductor element 12, and the insulating element 13. The conductive members 20 are formed from the same lead frame. The lead frame contains copper in its composition. As described above, the conductive members 20 include the first die pad 21, the second die pad 22, the third die pad 23, the first terminals 31, and the second terminals 32.

As shown in FIGS. 1 and 2, the first die pad 21 and the second die pad 22 are spaced apart from each other in the first direction x. The first semiconductor element 11 is mounted on the first die pad 21. The second semiconductor element 12 is mounted on the second die pad 22. The voltage applied to the second die pad 22 is higher than the voltage applied to the first die pad 21.

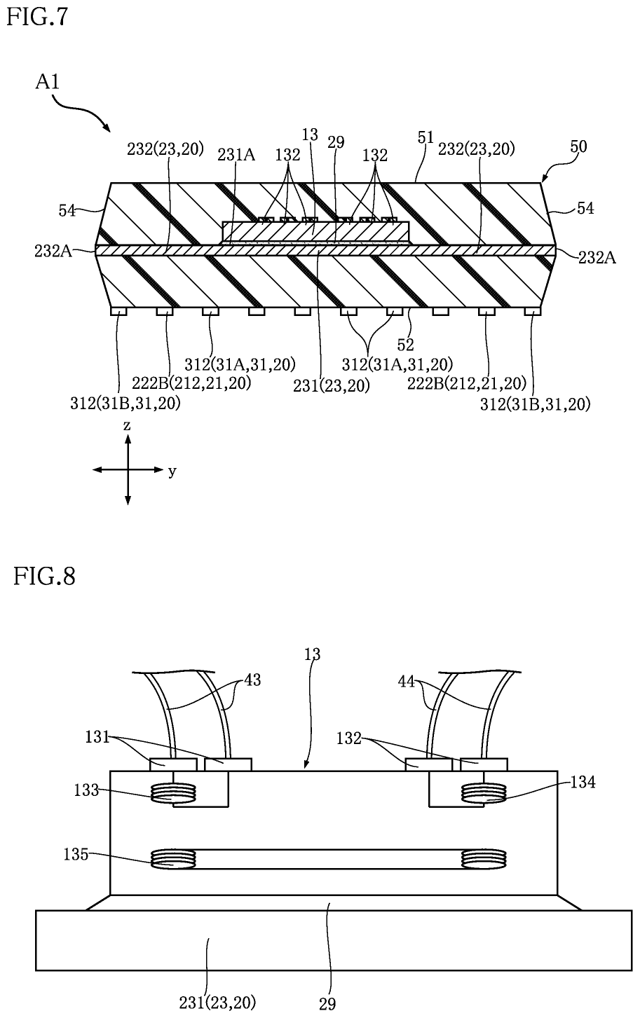

As shown in FIG. 2, the first die pad 21 has a first pad portion 211 and two first suspending lead portions 212. The first semiconductor element 11 is mounted on the first pad portion 211. As shown in FIGS. 6 and 7, the first pad portion 211 has a first mounting surface 211A facing in the thickness direction z. The first semiconductor element 11 is bonded to the first mounting surface 211A via a non-illustrated conductive bonding member (e.g., solder or metal paste). The first pad portion 211 is covered with the sealing resin 50. The first pad portion 211 has a thickness of about 150 μm to 200 μm, for example.

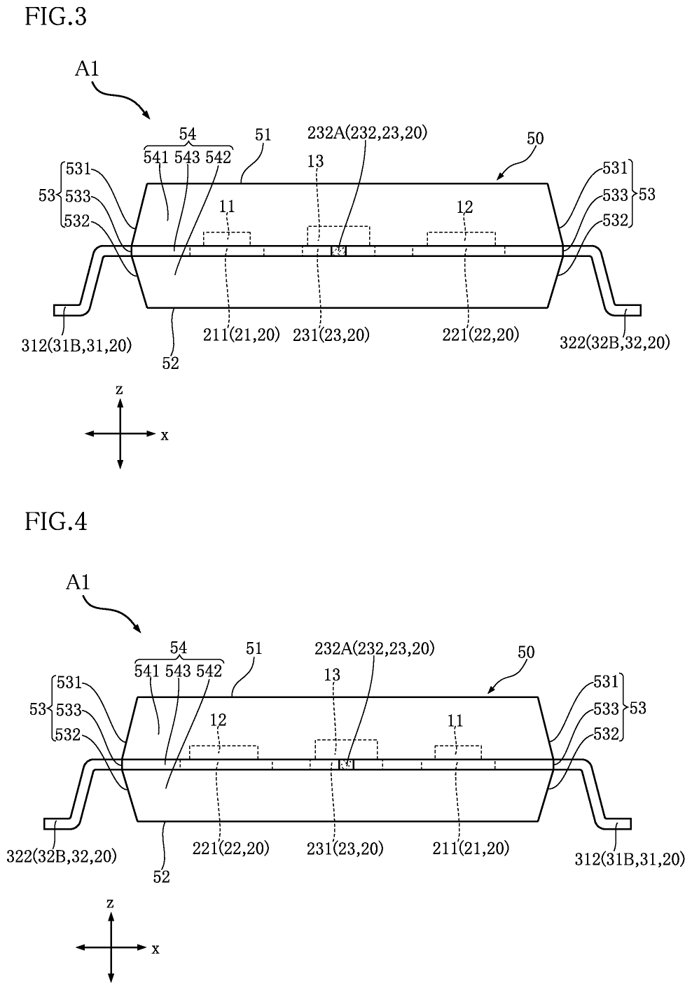

As shown in FIG. 2, the two first suspending lead portions 212 are connected to the respective sides of the first pad portion 211 in the second direction y. Each of the two first suspending lead portions 212 has a covered portion 212A and an exposed portion 212B. The covered portion 212A is connected to the first pad portion 211 and covered with the sealing resin 50. The covered portion 212A includes a section extending in the first direction x. The exposed portion 212B is connected to the covered portion 212A and exposed from the sealing resin 50. As viewed in the thickness direction z, the exposed portion 212B extends in the first direction x. As viewed in the second direction y, the exposed portion 212B is bent into a gull-wing shape (see FIGS. 3 and 4). The surface of the exposed portion 212B may be plated with tin (Sn), for example.

As shown in FIG. 2, the second die pad 22 has a second pad portion 221 and two second suspending lead portions 222. The second semiconductor element 12 is mounted on the second pad portion 221. As shown in FIG. 6, the second pad portion 221 has a second mounting surface 221A facing in the thickness direction z. The second semiconductor element 12 is bonded to the second mounting surface 221A via a non-illustrated conductive bonding member (e.g., solder or metal paste). The second pad portion 221 is covered with the sealing resin 50. The second pad portion 221 has a thickness of about 150 μm to 200 μm, for example.

As shown in FIG. 2, the two second suspending lead portions 222 extend from the respective sides of the second pad portion 221 in the second direction y. Each of the two second suspending lead portions 222 has a covered portion 222A and an exposed portion 222B. The covered portion 222A is connected to the second pad portion 221 and covered with the sealing resin 50. The covered portion 222A includes a section extending in the first direction x. The exposed portion 222B is connected to the covered portion 222A and exposed from the sealing resin 50. As viewed in the thickness direction z, the exposed portion 222B extends in the first direction x. As viewed in the second direction y, the exposed portion 222B is bent into a gull-wing shape (see FIGS. 2 and 4). The surface of the exposed portion 222B may be plated with tin, for example.

As shown FIGS. 1 and 2, the third die pad 23 is spaced apart from the first die pad 21 and the second die pad 22. The third die pad 23 is located between the first die pad 21 and the second die pad 22 in the first direction x. The insulating element 13 is mounted on the third die pad 23.

As shown in FIG. 2, the third die pad 23 has a third pad portion 231 and two third suspending lead portions 232. The insulating element 13 is mounted on the third pad portion 231. As shown in FIGS. 6 and 7, the third pad portion 231 has a third mounting surface 231A facing in the thickness direction z. The third pad portion 231 is covered with the sealing resin 50. The third pad portion 231 has a thickness of about 150 μm to 200 μm, for example. As viewed in the first direction x, the third pad portion 231 overlaps with the first pad portion 211 of the first die pad 21 and the second pad portion 221 of the second die pad 22. As shown in FIGS. 2 and 6, a distance P1 between the third pad portion 231 and the first pad portion 211 is equal to a distance P2 between the third pad portion 231 and the second pad portion 221.

As shown in FIG. 2, the two third suspending lead portions 232 are connected to the respective sides of the third pad portion 231 in the second direction y. The two third suspending lead portions 232 are exposed from a pair of second side surfaces 54 in the second direction y, respectively. The two third suspending lead portions 232 extend from the third pad portion 231 in the second direction y. Each of the two third suspending lead portions 232 has an end surface 232A. The end surface 232A faces in the second direction y. In each of the two third suspending lead portions 232, only the end surface 232A is exposed from the sealing resin 50. Since the third die pad 23 has the two third suspending lead portions 232, the third die pad 23 can be formed from the same lead frame from which the other conductive members 20 are formed.

As shown in FIGS. 6 and 7, the bonding layer 29 is located between the third pad portion 231 of the third die pad 23 and the insulating element 13. The insulating element 13 is bonded to the third mounting surface 231A of the third pad portion 231 via the bonding layer 29. The bonding layer 29 is electrically insulative. The bonding layer 29 is made of a material containing epoxy resin, for example.

As shown in FIGS. 1 and 2, the first terminals 31 are offset in one sense of the first direction x. Specifically, the first terminals 31 are located opposite from the second pad portion 221 of the second die pad 22 with respect to the first pad portion 211 of the first die pad 21 in the first direction x. The first terminals 31 are aligned in the second direction y. At least one of the first terminals 31 is electrically connected to the first semiconductor element 11 via a first wire 41. The plurality of first terminals 31 include a plurality of first inner terminals 31A and two first outer terminals 31B. The two first outer terminals 31B flank the first inner terminals 31A in the second direction y. In the second direction y, each of the two first suspending lead portions 212 of the first die pad 21 is located between one of the two first outer terminals 31B and the first inner terminal 31A closest to the first outer terminal 31B.

As shown in FIGS. 2 and 6, each of the first terminals 31 includes a covered portion 311 and an exposed portion 312. The covered portion 311 is covered with the sealing resin 50. The covered portion 311 of each of the two first outer terminals 31B is larger in dimension than the covered portion 311 of each of the first inner terminals 31A in the first direction x.

As shown in FIGS. 2 and 6, the exposed portion 312 is connected to the covered portion 311, and is exposed from the sealing resin 50. As viewed in the thickness direction z, the exposed portion 312 extends in the first direction x. The exposed portion 312 is bent into a gull-wing shape as viewed in the second direction y. The exposed portion 312 has the same shape as the exposed portion 212B of each of the two first suspending lead portions 212 of the first die pad 21. The surface of the exposed portion 312 may be plated with tin, for example.

As shown in FIGS. 1 and 2, the second terminals 32 are offset in the other sense of the first direction x. Specifically, the second terminals 32 are located opposite from the first terminals 31 with respect to the first pad portion 211 of the first die pad 21 in the first direction x. The second terminals 32 are aligned in the second direction y. At least one of the second terminals 32 is electrically connected to the second semiconductor element 12 via a second wire 42. The plurality of second terminals 32 include a plurality of second inner terminals 32A and two second outer terminals 32B. The two second outer terminals 32B flank the second inner terminals 32A in the second direction y. In the second direction y, each of the two second suspending lead portions 222 of the second die pad 22 is located between one of the two second outer terminals 32B and the second inner terminal 32A closest to the second outer terminal 32B.

As shown in FIGS. 2 and 6, each of the second terminals 32 has a covered portion 321 and an exposed portion 322. The covered portion 321 is covered with the sealing resin 50. The covered portion 321 of each of the two second outer terminals 32B is larger in dimension than the covered portion 321 of each of the second inner terminals 32A in the first direction x.

As shown in FIGS. 2 and 6, the exposed portion 322 is connected to the covered portion 321, and is exposed from the sealing resin 50. As viewed in the thickness direction z, the exposed portion 322 extends in the first direction x. As shown in FIG. 3, the exposed portion 322 is bent into a gull-wing shape as viewed in the second direction y. The exposed portion 322 has the same shape as the exposed portion 222B of each of the two second suspending lead portions 222 of the second die pad 22. The surface of the exposed portion 322 may be plated with tin, for example.

The first wires 41, the second wires 42, the third wires 43, and the fourth wires 44, as well as the conductive members 20, form a conductive path for the first semiconductor element 11, the second semiconductor element 12, and the insulating element 13 to perform predetermined functions.

As shown in FIGS. 2 and 6, the first wires 41 are bonded to the first electrodes 111 of the first semiconductor element 11 and the covered portions 311 of the first terminals 31. As a result, at least one of the first terminals 31 is electrically connected to the first semiconductor element 11. Furthermore, at least one of the first wires 41 is bonded to one of the first electrodes 111 and one of the covered portions 212A of the two first suspending lead portions 212 of the first die pad 21. As a result, the first semiconductor element 11 is electrically connected to at least one of the two first suspending lead portions 212. As such, at least one of the two first suspending lead portions 212 forms a ground terminal of the first semiconductor element 11. The composition of the first wires 41 includes gold (Au). Alternatively, the composition of the first wires 41 may include copper.

As shown in FIGS. 2 and 6, the second wires 42 are bonded to the second electrodes 121 of the second semiconductor element 12 and the covered portions 321 of the second terminals 32. As a result, at least one of the second terminals 32 is electrically connected to the second semiconductor element 12. Furthermore, at least one of the second wires 42 is bonded to one of the second electrodes 121 and one of the covered portions 222A of the two second suspending lead portions 222 of the second die pad 22. As a result, the second semiconductor element 12 is electrically connected to at least one of the two second suspending lead portions 222. As such, at least one of the two second suspending lead portions 222 forms a ground terminal of the second semiconductor element 12. The composition of the second wires 42 includes gold. Alternatively, the composition of the second wires 42 may include copper.

As shown in FIGS. 2 and 6, the third wires 43 are bonded to the first relay electrodes 131 of the insulating element 13 and the first electrodes 111 of the first semiconductor element 11. As a result, the first semiconductor element 11 and the insulating element 13 are electrically connected to each other. The third wires 43 are aligned in the second direction y. The third wires 43 extend across the first pad portion 211 of the first die pad 21 and the third pad portion 231 of the third die pad 23. The composition of the third wires 43 includes gold.

As shown in FIGS. 2 and 6, the fourth wires 44 are bonded to the second relay electrodes 132 of the insulating element 13 and the second electrodes 121 of the second semiconductor element 12. As a result, the second semiconductor element 12 and the insulating element 13 are electrically connected to each other. The fourth wires 44 are aligned in the second direction y. The fourth wires 44 extend across the third pad portion 231 of the third die pad 23 and the second pad portion 221 of the second die pad 22. The composition of the fourth wires 44 includes gold.

As shown in FIG. 1, the sealing resin 50 covers the first semiconductor element 11, the second semiconductor element 12, the insulating element 13, and at least a portion of each of the conductive members 20. Furthermore, the sealing resin 50 covers the first wires 41, the second wires 42, the third wires 43, and the fourth wires 44. The sealing resin 50 is electrically insulative. The sealing resin 50 is made of a material containing epoxy resin, for example. As viewed in the thickness direction z, the sealing resin 50 has a rectangular shape.

As shown in FIGS. 3 to 5, the sealing resin 50 has a top surface 51, a bottom surface 52, a pair of first side surfaces 53, and a pair of second side surfaces 54.

As shown in FIGS. 3 to 5, the top surface 51 and the bottom surface 52 are spaced apart from each other in the thickness direction z. The top surface 51 and the bottom surface 52 face away from each other in the thickness direction z. Each of the top surface 51 and the bottom surface 52 is flat (or substantially flat).

As shown in FIGS. 3 to 5, the pair of first side surfaces 53 are connected to the top surface 51 and the bottom surface 52, and are spaced apart from each other in the first direction x. The exposed portions 212B of the two first suspending lead portions 212 of the first die pad 21 and the exposed portions 312 of the first terminals 31 are exposed from one of the pair of first side surfaces 53 that is offset in one sense of the first direction x. The exposed portions 222B of the two second suspending lead portions 222 of the second die pad 22 and the exposed portions 322 of the second terminals 32 are exposed from one of the pair of first side surfaces 53 that is offset in the other sense of the first direction x.

As shown in FIGS. 3 to 5, each of the pair of first side surfaces 53 includes a first upper portion 531, a first lower portion 532, and a first intermediate portion 533. One end of the first upper portion 531 in the thickness direction z is connected to the top surface 51, and the other end thereof in the thickness direction z is connected to the first intermediate portion 533. The first upper portion 531 is inclined relative to the top surface 51. One end of the first lower portion 532 in the thickness direction z is connected to the bottom surface 52, and the other end thereof in the thickness direction z is connected to the first intermediate portion 533. The first lower portion 532 is inclined relative to the bottom surface 52. One end of the first intermediate portion 533 in the thickness direction z is connected to the first upper portion 531, and the other end thereof in the thickness direction z is connected to the first lower portion 532. The in-plane directions of the first intermediate portion 533 are the thickness direction z and the second direction y. As viewed in the thickness direction z, the first intermediate portion 533 is located more outward than the top surface 51 and the bottom surface 52. The exposed portions 212B of the two first suspending lead portions 212 of the first die pad 21, the exposed portions 222B of the two second suspending lead portions 222 of the second die pad 22, the exposed portions 312 of the first terminals 31, and the exposed portions 322 of the second terminals 32 are exposed from the first intermediate portions 533 of the pair of first side surfaces 53.

As shown in FIGS. 3 to 5, the pair of second side surfaces 54 are connected to the top surface 51 and the bottom surface 52, and are spaced apart from each other in the second direction y. As shown in FIG. 1, the first die pad 21, the second die pad 22, the first terminals 31, and the second terminals 32 are located away from the pair of second side surfaces 54. The end surfaces 232A of the two third suspending lead portions 232 of the third die pad 23 are exposed from the pair of second side surfaces 54.

As shown in FIGS. 3 to 5, each of the pair of second side surfaces 54 includes a second upper portion 541, a second lower portion 542, and a second intermediate portion 543. One end of the second upper portion 541 in the thickness direction is connected to the top surface 51, and the other end thereof in the thickness direction z is connected to the second intermediate portion 543. The second upper portion 541 is inclined relative to the top surface 51. One end of the second lower portion 542 in the thickness direction z is connected to the bottom surface 52, and the other end thereof in the thickness direction z is connected to the second intermediate portion 543. The second lower portion 542 is inclined relative to the bottom surface 52. One end of the second intermediate portion 543 in the thickness direction z is connected to the second upper portion 541, and the other end thereof in the thickness direction z is connected to the second lower portion 542. The in-plane directions of the second intermediate portion 543 are the thickness direction z and the first direction x. As viewed in the thickness direction z, the second intermediate portion 543 is located more outward than the top surface 51 and the bottom surface 52. The end surfaces 232A of the two third suspending lead portions 232 of the third die pad 23 are exposed from the second intermediate portions 543 of the pair of second side surfaces 54.

A motor driver circuit for an inverter is typically configured with a half-bridge circuit including a low-side (low-potential-side) switching element and a high-side (high-potential-side) switching element. The following description is provided with an assumption that these switching elements are MOSFETs. Note that the reference potential of the source of the low-side switching element and the reference potential of the gate driver for driving the low-side switching element are both ground. On the other hand, the reference potential of the source of the high-side switching element and the reference potential of the gate driver for driving the high-side switching element both correspond to a potential at an output node of the half-bridge circuit. Because the potential at the output node varies according to the drive of the high-side switching element and the low-side switching element, the reference potential of the gate driver for driving the high-side switching element varies as well. When the high-side switching element is on, the reference potential is equivalent to the voltage applied to the drain of the high-side switching element (e.g., 600 V or higher). In the semiconductor device A1, the ground of the first semiconductor element 11 is spaced apart from the ground of the second semiconductor element 12. Accordingly, in the case where the semiconductor device A1 is used as the gate driver for driving the high-side switching element, a voltage equivalent to the voltage applied to the drain of the high-side switching element is transiently applied to the ground of the second semiconductor element 12.

The following describes advantages of the semiconductor device A1.

The semiconductor device A1 includes the conductive members 20 including the first die pad 21 and the second die pad 22, the first semiconductor element 11 mounted on the first die pad 21, the second semiconductor element 12 mounted on the second die pad 22, and the insulating element 13 that insulates the first semiconductor element 11 and the second semiconductor element 12 from each other. The conductive members 20 further include the third die pad 23 spaced apart from the first die pad 21 and the second die pad 22. The insulating element 13 is mounted on the third die pad 23. With this configuration, the third die pad 23 electrically floats with respect to the first die pad 21 and the second die pad 22. This prevents the movement of charged carriers from the first semiconductor element 11 and the second semiconductor element 12 to the insulating element 13. Accordingly, the semiconductor device A1 is capable of improving the dielectric strength between the insulating element 13 and each of the semiconductor elements (i.e., the first semiconductor element 11 and the second semiconductor element 12).

The semiconductor device A1 further includes the sealing resin 50 that covers the first semiconductor element 11, the second semiconductor element 12, the insulating element 13, and at least a portion of each of the conductive members 20. In this way, the third die pad 23, as well as the other conductive members 20, is supported by the sealing resin 50. Furthermore, a portion of the sealing resin 50 is located at each of the area between the third die pad 23 and the first die pad 21 and the area between the third die pad 23 and the second die pad 22. This makes it possible to improve the dielectric strength of the area between the third die pad 23 and the first die pad 21 and the area between the third die pad 23 and the second die pad 22.

The semiconductor device A1 further includes the bonding layer 29 between the third die pad 23 and the insulating element 13. It is preferable that the bonding layer 29 be electrically insulative. This effectively prevents the movement of charged carriers from an upper surface of the third die pad 23 (the third mounting surface 231A of the third pad portion 231) to a lower surface of the insulating element 13 facing the upper surface.

The insulating element 13 has the first transceiver 133, the second transceiver 134, and the relay portion 135. In the thickness direction z, the relay portion 135 is located closer to the third die pad 23 than are the first transceiver 133 and the second transceiver 134. This configuration allows the potential difference between the first transceiver 133 and the relay portion 135 and the potential difference between the second transceiver 134 and the relay portion 135 to be set smaller in the insulating element 13. As a result, the dielectric strength of the insulating element 13 can be improved. Furthermore, the potential difference between the upper surface of the third die pad 23 (the third mounting surface 231A of the third pad portion 231) and the lower surface of the insulating element 13 facing the upper surface is reduced. Thus, it is possible to effectively improve the dielectric strength between the third die pad 23 and the insulating element 13.

In the semiconductor device A1, a portion of each of the conductive members 20 is exposed from either one of the pair of first side surfaces 53 of the sealing resin 50. This configuration can be obtained by allowing the two first suspending lead portions 212 of the first die pad 21 to be exposed from one side of the sealing resin 50 in the first direction x, and also allowing the two second suspending lead portions 222 of the second die pad 22 to be exposed from the other side of the sealing resin 50 in the first direction x. In this case, the conductive members 20, except for the two third suspending lead portions 232 of the third die pad 23, are located away from the pair of second side surfaces 54 of the sealing resin 50. This makes it possible to suppress a decrease in the dielectric strength of the semiconductor device A1 caused by the conductive members 20.

The first die pad 21 and the second die pad 22 are spaced apart from each other in the first direction x. The third die pad 23 is located between the first die pad 21 and the second die pad 22 in the first direction x. With this configuration, the two third suspending lead portions 232 of the third die pad 23 can be arranged between a group including the two first suspending lead portions 212 of the first die pad 21 and the first terminals 31 and another group including the two second suspending lead portions 222 of the second die pad 22 and the second terminals 32 in the first direction x. This allows the creepage distance of the sealing resin 50 from the two third suspending lead portions 232 to the first terminals 31 and the creepage distance of the sealing resin from the two third suspending lead portions 232 to the second terminals 32 to be equal to each other. As such, a local decrease in the dielectric strength of the semiconductor device A1 can be prevented.

The following describes a semiconductor device A2 according to a second embodiment of the present disclosure, with reference to FIGS. 9 to 11. In these figures, elements that are the same as or similar to the elements of the semiconductor device A1 described above are provided with the same reference signs, and descriptions thereof are omitted. In FIG. 9, the sealing resin 50 is shown in phantom for convenience of understanding, and is indicated by an imaginary line.

The semiconductor device A2 is different from the semiconductor device A1 in the configuration of the third die pad 23.

As shown in FIG. 9, each of the two third suspending lead portions 232 of the third die pad 23 includes a first suspending portion 232B and a second suspending portion 232C. The first suspending portion 232B and the second suspending portion 232C are spaced apart from each other in the first direction x. Each of the first suspending portion 232B and the second suspending portion 232C has an end surface 232A. The first suspending portion 232B and the second suspending portion 232C extend from the third pad portion 231 of the third die pad 23 in the second direction y.

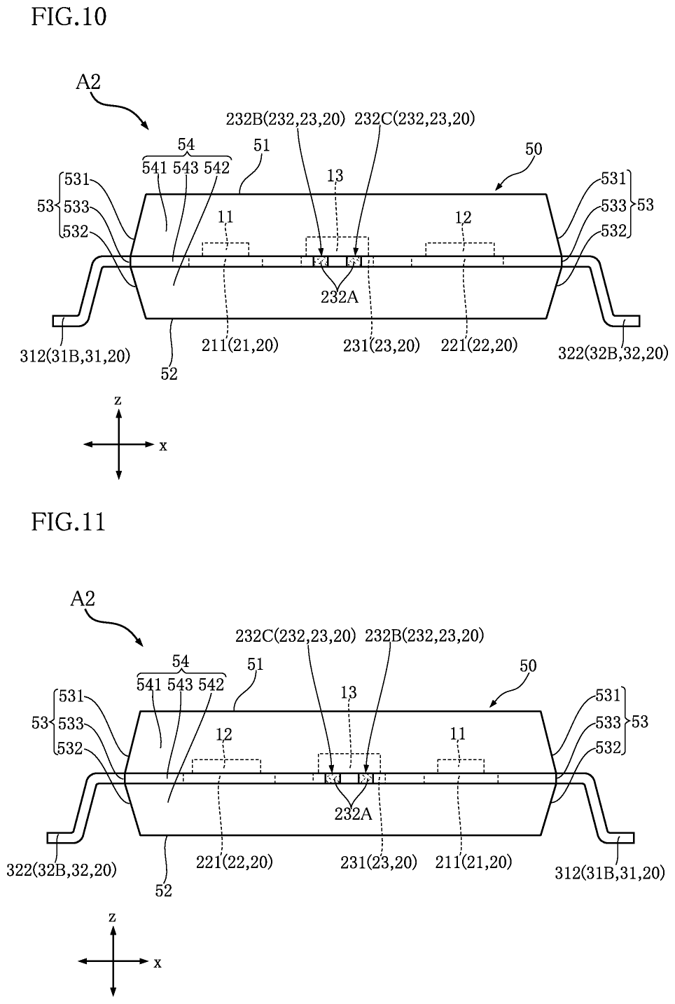

As shown in FIGS. 10 and 11, the end surfaces 232A of the first suspending portion 232B and the second suspending portion 232C of each of the two third suspending lead portions 232 are exposed from the second intermediate portion 543 of one of the pair of second side surfaces 54 of the sealing resin 50.

The following describes advantages of the semiconductor device A2.

The semiconductor device A2 includes the conductive members 20 including the first die pad 21 and the second die pad 22, the first semiconductor element 11 mounted on the first die pad 21, the second semiconductor element 12 mounted on the second die pad 22, and the insulating element 13 that insulates the first semiconductor element 11 and the second semiconductor element 12 from each other. The conductive members 20 further include the third die pad 23 spaced apart from the first die pad 21 and the second die pad 22. The insulating element 13 is mounted on the third die pad 23. Accordingly, the semiconductor device A2 is also capable of improving the dielectric strength between the insulating element 13 and each of the semiconductor elements (i.e., the first semiconductor element 11 and the second semiconductor element 12). Furthermore, the semiconductor device A2 adopts a configuration common to the semiconductor device A1, and thereby achieves advantages similar to those achieved by the semiconductor device A1.

Each of the two third suspending lead portions 232 of the third die pad 23 in the semiconductor device A2 includes a first suspending portion 232B and a second suspending portion 232C spaced apart from each other in the first direction x. In this example, the bending rigidity of each of the two third suspending lead portions 232 around the first direction x can be improved by designing the area of the end surface 232A of each of the first suspending portion 232B and the second suspending portion 232C to be larger than or equal to the area of the end surface 232A of each of the two third suspending lead portions 232 of the semiconductor device A1. In this way, when the insulating element 13 is mounted on the third die pad 23 during the manufacture of the semiconductor device A2, the amount of deflection of the two third suspending lead portions 232 can be suppressed. This further suppresses shortening of the distance from the bottom surface 52 of the sealing resin 50 to the third pad portion 231 of the third die pad 23 in the thickness direction z, thus avoiding a decrease in the dielectric strength of the semiconductor device A2. Furthermore, since the sealing resin 50 is fluidized and passes between the first suspending portion 232B and the second suspending portion 232C during the manufacturing of the semiconductor device A2, insufficient filling of the sealing resin 50 can be prevented. This suppresses the creation of voids in the sealing resin 50.

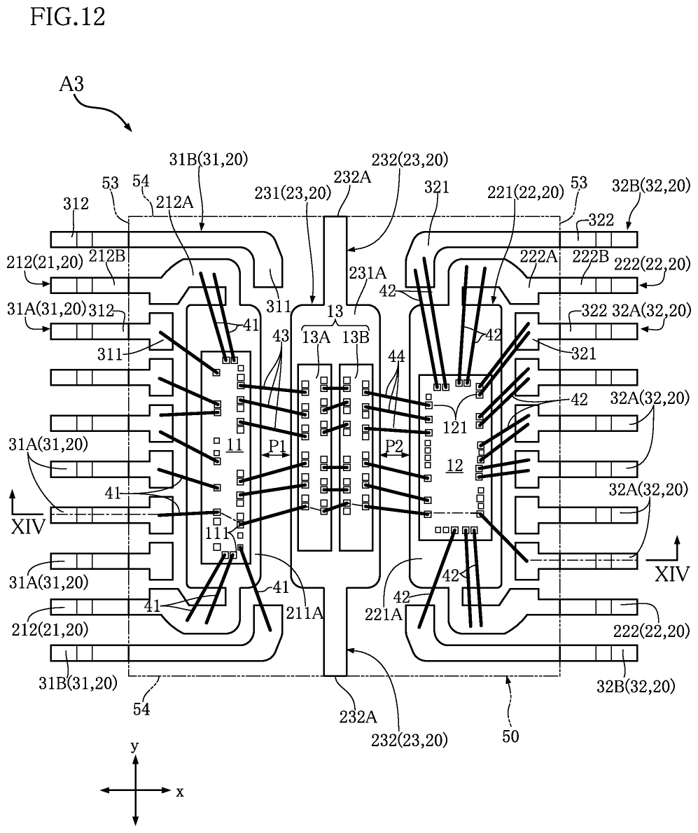

The following describes a semiconductor device A3 according to a third embodiment of the present disclosure, with reference to FIGS. 12 to 15. In these figures, elements that are the same as or similar to the elements of the semiconductor device A1 described above are provided with the same reference signs, and descriptions thereof are omitted. In FIG. 12, the sealing resin 50 is shown in phantom for convenience of understanding, and is indicated by an imaginary line.

The semiconductor device A3 is different from the semiconductor device A1 in the configuration of an insulator (insulating element) 13. The semiconductor device A3 further includes a plurality of fifth wires 45.

As shown in FIGS. 12 to 14, the insulator 13 includes a first insulating element 13A and a second insulating element 13B that are spaced apart from each other. In the semiconductor device A3, the first insulating element 13A and the second insulating element 13B are spaced apart from each other in the first direction x such that the first insulating element 13A is closer to the first semiconductor element 11 than is the second insulating element 13B. The first insulating element 13A and the second insulating element 13B are bonded to the third mounting surface 231A of the third pad portion 231 of the third die pad 23 via the bonding layer 29. In the semiconductor device A3, the bonding layer 29 is a single layer. Alternatively, the bonding layer 29 may be divided into a plurality of sublayers as in the first insulating element 13A and the second insulating element 13B.

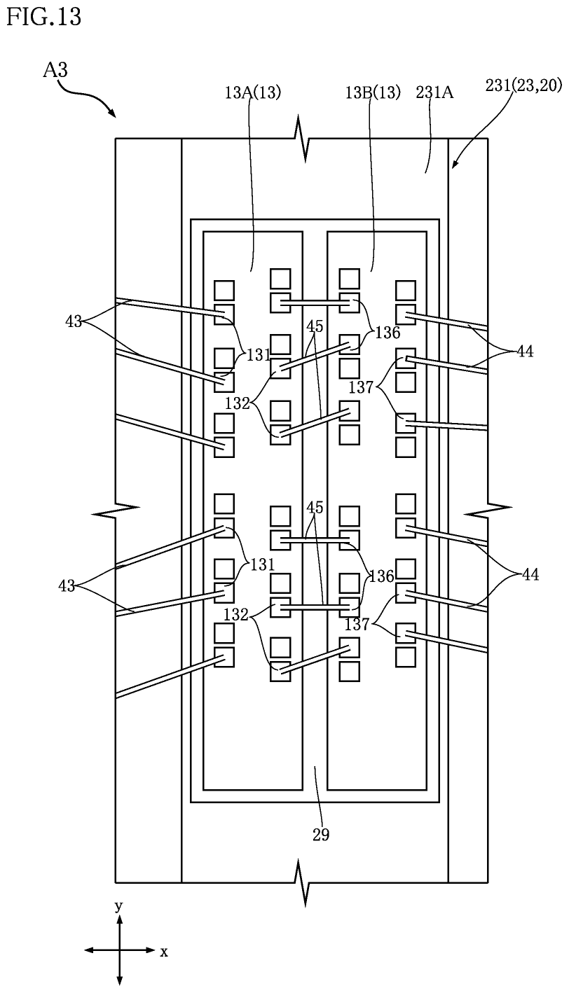

As shown in FIG. 13, the first insulating element 13A has a plurality of first relay electrodes 131 and a plurality of second relay electrodes 132. The third wires 43 are bonded to the first relay electrodes 131 and the first electrodes 111 of the first semiconductor element 11. Accordingly, the first relay electrodes 131 are electrically connected to the first semiconductor element 11.

As shown in FIG. 15, the first insulating element 13A has a first transceiver 133 and a second transceiver 134. In the semiconductor device A3, the first transceiver 133 and the second transceiver 134 are inductors. The first transceiver 133 and the second transceiver 134 are spaced apart from each other in the thickness direction z. In the first insulating element 13A, a dielectric layer (not illustrated) made of, for example, silicon dioxide, is provided between the first transceiver 133 and the second transceiver 134. The first transceiver 133 is electrically connected to the first relay electrodes 131. Accordingly, the first transceiver 133 is electrically connected to the first semiconductor element 11. The second transceiver 134 transmits and receives signals to and from the first transceiver 133. The second transceiver 134 is electrically connected to the second relay electrodes 132. The second transceiver 134 is located closer to the third pad portion 231 of the third die pad 23 than is the first transceiver 133 in the thickness direction z.

As shown in FIG. 13, the second insulating element 13B has a plurality of third relay electrodes 136 and a plurality of fourth relay electrodes 137. The fourth wires 44 are bonded to the fourth relay electrodes 137 and the second electrodes 121 of second semiconductor element 12. Accordingly, the fourth relay electrodes 137 are electrically connected to the second semiconductor element 12.

As shown in FIG. 15, the second insulating element 13B has a third transceiver 138 and a fourth transceiver 139. In the semiconductor device A3, the third transceiver 138 and the fourth transceiver 139 are inductors. The third transceiver 138 and the fourth transceiver 139 are spaced apart from each other in the thickness direction z. In the second insulating element 13B, a dielectric layer (not illustrated) made of, for example, silicon dioxide, is provided between the third transceiver 138 and the fourth transceiver 139. The fourth transceiver 139 is electrically connected to the fourth relay electrodes 137. Accordingly, the fourth transceiver 139 is electrically connected to the second semiconductor element 12. The third transceiver 138 transmits and receives signals to and from the fourth transceiver 139. The third transceiver 138 is electrically connected to the third relay electrodes 136. The third transceiver 138 is located closer to the third pad portion 231 of the third die pad 23 than is the fourth transceiver 139 in the thickness direction z.

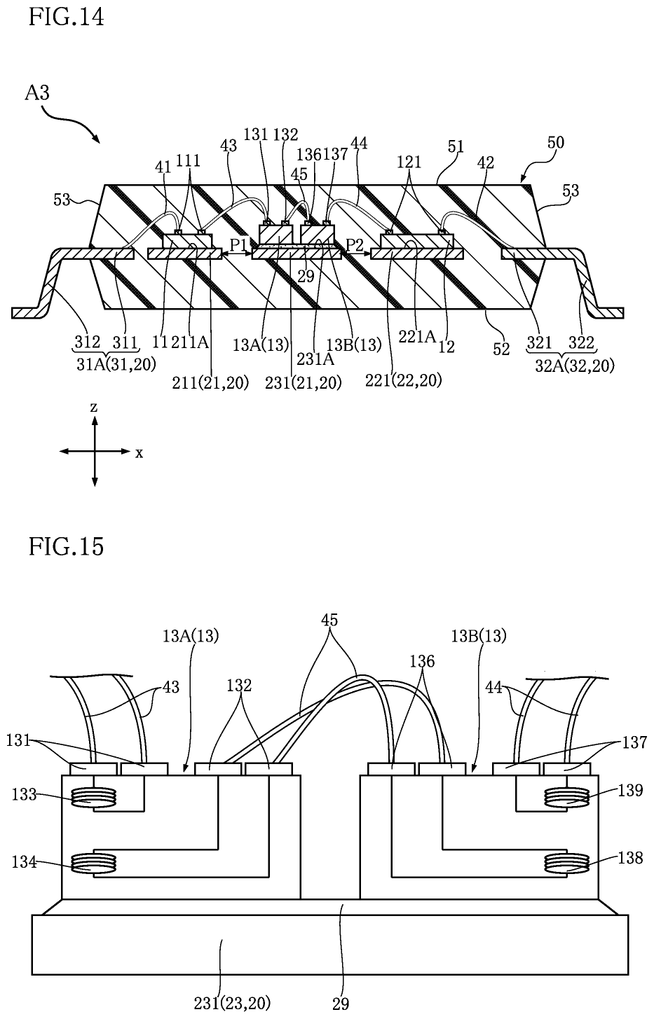

As shown in FIGS. 13 and 14, the fifth wires 45 are bonded to the third relay electrodes 136 of the second insulating element 13B and the first relay electrodes 131 of the first insulating element 13A. The composition of the fifth wires 45 includes gold. This electrically connects the second relay electrodes 132 and the third relay electrodes 136 to each other. As a result, the third transceiver 138 of the second insulating element 13B is electrically connected to the second transceiver 134 of the first insulating element 13A. As such, the potential of the third transceiver 138 is equal to the potential of the second transceiver 134. Based on the above, the potential of each of the second transceiver 134 and the third transceiver 138 takes a value between the potential of the first transceiver 133 of the first insulating element 13A and the potential of the fourth transceiver 139 of the second insulating element 13B.

The following describes advantages of the semiconductor device A3.

The semiconductor device A3 includes the conductive members 20 including the first die pad 21 and the second die pad 22, the first semiconductor element 11 mounted on the first die pad 21, the second semiconductor element 12 mounted on the second die pad 22, and the insulator 13 that insulates the first semiconductor element 11 and the second semiconductor element 12 from each other. The conductive members 20 further include the third die pad 23 spaced apart from the first die pad 21 and the second die pad 22. The insulator 13 is mounted on the third die pad 23. Accordingly, the semiconductor device A3 is also capable of improving the dielectric strength between the insulator 13 and each of the semiconductor elements (i.e., the first semiconductor element 11 and the second semiconductor element 12). Furthermore, the semiconductor device A3 adopts a configuration common to the semiconductor device A1, and thereby achieves advantages similar to those achieved by the semiconductor device A1.

The insulator 13 of the semiconductor device A3 includes the first insulating element 13A and the second insulating element 13B that are spaced apart from each other. The first insulating element 13A has the first transceiver 133 and the second transceiver 134. The second insulating element 13B has the third transceiver 138 and the fourth transceiver 139. The third transceiver 138 is electrically connected to the second transceiver 134. The second transceiver 134 and the third transceiver 138 are located closer to the third die pad 23 than are the first transceiver 133 and the fourth transceiver 139 in the thickness direction z. This allows the potential difference between the first transceiver 133 and the second transceiver 134 to be set smaller in the first insulating element 13A. Furthermore, the potential difference between the third transceiver 138 and the fourth transceiver 139 can also be set smaller in the second insulating element 13B. In other words, it is possible to reduce the potential difference that occurs in each of the first insulating element 13A and the second insulating element 13B. Furthermore, the potential difference between the upper surface of the third die pad 23 (the third mounting surface 231A of the third pad portion 231) and the lower surface of the insulator 13 facing the upper surface is reduced. Thus, it is possible to effectively improve the dielectric strength between the third die pad 23 and the insulator 13. Furthermore, the semiconductor device A3 is different from the semiconductor device A1 in that it is not necessary to provide the relay portion 135 in the insulator 13.

The present disclosure is not limited to the foregoing embodiments. Various design changes can be made to the specific configurations of the elements of the present disclosure.

The present disclosure includes embodiments described in the following clauses.

Clause 1.

A semiconductor device comprising:
a plurality of conductive members including a first die pad and a second die pad that are spaced apart from each other;
a first semiconductor element mounted on the first die pad;
a second semiconductor element mounted on the second die pad; and
an insulator that is electrically connected to the first semiconductor element and the second semiconductor element, and that insulates the first semiconductor element and the second semiconductor element from each other,
wherein the plurality of conductive members include a third die pad spaced apart from the first die pad and the second die pad, and
the insulator is mounted on the third die pad.

Clause 2.

The semiconductor device according to clause 1, further comprising a sealing resin covering the first semiconductor element, the second semiconductor element, the insulator, and at least a portion of each of the plurality of conductive members.

Clause 3.

The semiconductor device according to clause 2, wherein the first die pad and the second die pad are spaced apart from each other in a first direction perpendicular to a thickness direction of each of the first semiconductor element and the second semiconductor element, and
the third die pad is located between the first die pad and the second die pad in the first direction.

Clause 4.

The semiconductor device according to clause 3, wherein the plurality of conductive members include a plurality of first terminals exposed from one side of the sealing resin in the first direction, and a plurality of second terminals exposed from another side of the sealing resin in the first direction,
the first semiconductor element is electrically connected to the plurality of first terminals, and
the second semiconductor element is electrically connected to the plurality of second terminals.

Clause 5.

The semiconductor device according to clause 4, wherein the plurality of first terminals and the plurality of second terminals are aligned in a second direction perpendicular to both of the thickness direction and the first direction.

Clause 6.

The semiconductor device according to clause 5, wherein the first die pad has a first pad portion on which the first semiconductor element is mounted, and two first suspending lead portions connected to respective sides of the first pad portion in the second direction, and
the two first suspending lead portions are exposed from the one side of the sealing resin in the first direction.

Clause 7.

The semiconductor device according to clause 6, wherein the first semiconductor element is electrically connected to at least one of the two first suspending lead portions.

Clause 8.

The semiconductor device according to clause 6 or 7, wherein the second die pad has a second pad portion on which the second semiconductor element is mounted, and two second suspending lead portions connected to respective sides of the second pad portion in the second direction, and the two second suspending lead portions are exposed from the other side of the sealing resin in the first direction.

Clause 9.

The semiconductor device according to clause 8, wherein the second semiconductor element is electrically connected to at least one of the two second suspending lead portions.

Clause 10.

The semiconductor device according to clause 8 or 9, wherein the third die pad has a third pad portion on which the insulator is mounted, and two third suspending lead portions connected to respective sides of the third pad portion in the second direction, and
the two third suspending lead portions are exposed from respective sides of the sealing resin in the second direction.

Clause 11.

The semiconductor device according to clause 10, wherein the two third suspending lead portions extend from the third pad portion in the second direction.

Clause 12.

The semiconductor device according to clause 11, wherein as viewed in the first direction, the third pad portion overlaps with the first pad portion and the second pad portion.

Clause 13.

The semiconductor device according to any of clauses 1 to 12, wherein the insulator is of a type that is one of an inductive type and a capacitive type.

Clause 14.

The semiconductor device according to clause 13, wherein the insulator has a first transceiver electrically connected to the first semiconductor element, a second transceiver electrically connected to the second semiconductor element, and a relay portion that transmits and receives signals between the first transceiver and the second transceiver, and
in a thickness direction of the insulator, the relay portion is located closer to the third die pad than are the first transceiver and the second transceiver.

Clause 15.

The semiconductor device according to clause 13, wherein the insulator includes a first insulating element and a second insulating element that are spaced apart from each other,
the first insulating element has a first transceiver electrically connected to the first semiconductor element, and a second transceiver that transmits and receives signals to and from the first transceiver,
the second insulating element has a third transceiver electrically connected to the second transceiver, and a fourth transceiver that transmits and receives signals to and from the third transceiver, and
in a thickness direction of the insulator, the second transceiver and the third transceiver are located closer to the third die pad than are the first transceiver and the fourth transceiver.

Clause 16.

The semiconductor device according to any of clauses 1 to 14, further comprising a bonding layer provided between the third die pad and the insulator, and
the bonding layer is electrically insulative.

### REFERENCE SIGNS

A1, A2, A3: Semiconductor device
11: First semiconductor element
111: First electrode
12: Second semiconductor element
121: Second electrode
13: Insulating element
13A: First insulating element
13B: Second insulating element
131: First relay electrode
132: Second relay electrode
133: First transceiver
134: Second transceiver
135: Relay portion
136: Third relay electrode
137: Fourth relay electrode
138: Third transceiver
139: Fourth transceiver
20: Conductive member
21: First die pad
211: First pad portion
211A: First mounting surface
212: First suspending lead portion
212A: Covered portion
212B: Exposed portion
22: Second die pad
221: Second pad portion
221A: Second mounting surface
222: Second suspending lead portion
222A: Covered portion
222B: Exposed portion
23: Third die pad
231: Third pad portion
231A: Third mounting surface
232: Third suspending lead portion
232A: End surface
232B: First suspending portion
232C: Second suspending portion
29: Bonding layer
31: First terminal
31A: First inner terminal
31B: First outer terminal
311: Covered portion
312: Exposed portion
32: Second terminal
32A: Second inner terminal
32B: Second outer terminal
321: Covered portion
322: Exposed portion
41: First wire
42: Second wire
43: Third wire
44: Fourth wire
45: Fifth wire
50: Sealing resin
51: Top surface
52: Bottom surface
53: First side surface
531: First upper portion
532: First lower portion
533: First intermediate portion
54: Second side surface
541: Second upper portion
542: Second lower portion
543: Second intermediate portion
P1, P2: Distance
z: Thickness direction
x: First direction
y: Second direction

1. A semiconductor device comprising:
a plurality of conductive members including a first die pad and a second die pad that are spaced apart from each other;
a first semiconductor element mounted on the first die pad;
a second semiconductor element mounted on the second die pad; and
an insulator that is electrically connected to the first semiconductor element and the second semiconductor element, and that insulates the first semiconductor element and the second semiconductor element from each other,
wherein the plurality of conductive members include a third die pad spaced apart from the first die pad and the second die pad, and
the insulator is mounted on the third die pad.

2. The semiconductor device according to claim 1, further comprising a sealing resin covering the first semiconductor element, the second semiconductor element, the insulator, and at least a portion of each of the plurality of conductive members.

3. The semiconductor device according to claim 2, wherein the first die pad and the second die pad are spaced apart from each other in a first direction perpendicular to a thickness direction of each of the first semiconductor element and the second semiconductor element, and
the third die pad is located between the first die pad and the second die pad in the first direction.

4. The semiconductor device according to claim 3, wherein the plurality of conductive members include a plurality of first terminals exposed from one side of the sealing resin in the first direction, and a plurality of second terminals exposed from another side of the sealing resin in the first direction,
the first semiconductor element is electrically connected to the plurality of first terminals, and
the second semiconductor element is electrically connected to the plurality of second terminals.

5. The semiconductor device according to claim 4, wherein the plurality of first terminals and the plurality of second terminals are aligned in a second direction perpendicular to both of the thickness direction and the first direction.

6. The semiconductor device according to claim 5, wherein the first die pad has a first pad portion on which the first semiconductor element is mounted, and two first suspending lead portions connected to respective sides of the first pad portion in the second direction, and
the two first suspending lead portions are exposed from the one side of the sealing resin in the first direction.

7. The semiconductor device according to claim 6, wherein the first semiconductor element is electrically connected to at least one of the two first suspending lead portions.

8. The semiconductor device according to claim 6, wherein the second die pad has a second pad portion on which the second semiconductor element is mounted, and two second suspending lead portions connected to respective sides of the second pad portion in the second direction, and
the two second suspending lead portions are exposed from the other side of the sealing resin in the first direction.

9. The semiconductor device according to claim 8, wherein the second semiconductor element is electrically connected to at least one of the two second suspending lead portions.

10. The semiconductor device according to claim 8, wherein the third die pad has a third pad portion on which the insulator is mounted, and two third suspending lead portions connected to respective sides of the third pad portion in the second direction, and
the two third suspending lead portions are exposed from respective sides of the sealing resin in the second direction.

11. The semiconductor device according to claim 10, wherein the two third suspending lead portions extend from the third pad portion in the second direction.

12. The semiconductor device according to claim 11, wherein as viewed in the first direction, the third pad portion overlaps with the first pad portion and the second pad portion.

13. The semiconductor device according to claim 1, wherein the insulator is of a type that is one of an inductive type and a capacitive type.

14. The semiconductor device according to claim 13, wherein the insulator has a first transceiver electrically connected to the first semiconductor element, a second transceiver electrically connected to the second semiconductor element, and a relay portion that transmits and receives signals between the first transceiver and the second transceiver, and
in a thickness direction of the insulator, the relay portion is located closer to the third die pad than are the first transceiver and the second transceiver.

15. The semiconductor device according to claim 13, wherein the insulator includes a first insulating element and a second insulating element that are spaced apart from each other,
the first insulating element has a first transceiver electrically connected to the first semiconductor element, and a second transceiver that transmits and receives signals to and from the first transceiver,
the second insulating element has a third transceiver electrically connected to the second transceiver, and a fourth transceiver that transmits and receives signals to and from the third transceiver, and
in a thickness direction of the insulator, the second transceiver and the third transceiver are located closer to the third die pad than are the first transceiver and the fourth transceiver.

16. The semiconductor device according to claim 1, further comprising a bonding layer provided between the third die pad and the insulator, and
the bonding layer is electrically insulative.
